(19) United States
(12) Patent Application Publication
(10) Pub. No.: US 2013/0320960 A1
(43) Pub. Date: Dec. 5, 2013

(54) APPARATUS AND METHODS FOR MEASURING A CURRENT

(71) Applicants: David Soriano Fosas, Terrassa (ES); Juan Luis López Rodriguez, Subirats Barcelona (ES); Vicente Granados Asensio, (US)

(72) Inventors: David Soriano Fosas, Terrassa (ES); Juan Luis López Rodriguez, Subirats Barcelona (ES); Vicente Granados Asensio, (US)

(21) Appl. No.: 13/482,885

(22) Filed: May 29, 2012

(51) Int. Cl. G01R 19/15

(52) U.S. Cl. 324/120

(57) ABSTRACT

An apparatus and methods for measuring a current flowing into an electrical device are described. In the apparatus, a current sensing circuit has at least one monolithic device, which in turn has a positive operating voltage and a negative operating voltage. The current sensing circuit is coupled to a power supply for the electrical device and the at least one monolithic device is arranged to enable a signal representative of the input current from the power supply to the electrical device to be output. The apparatus also has a power converter for converting a first voltage output by the power supply to a second voltage for supply as the positive operating voltage and a voltage clamp arranged to clamp the difference between the positive and negative operating voltages.

### BACKGROUND

Many electrical devices require high-voltage power supplies. For example, one or more electrical circuits that comprise an electrical device may require a 24 V or 32 V power supply. Often it is useful to measure an input current for such electrical devices. This may be required for testing or ensuring correct operation of an electrical device. However, measuring an input current for a high-voltage electrical device is difficult.

One way to measure an input current for a high-voltage electrical device is to use a dedicated integrated circuit. However, such integrated circuits incorporate complex circuitry and are often expensive. US2003/0117121 A1 describes an electrical circuit that includes an electrical device in the form of an optical receiver circuit. This circuit is operated at a relatively high voltage, i.e. the device has a high-side current node. The electrical circuit also includes a current mirror circuit, which senses a current into said high-side node, and which includes at least one monolithic device. The monolithic device is illustratively a rail-to-rail input operational amplifier.

### BRIEF DESCRIPTION OF THE DRAWINGS

Various features and advantages of the present disclosure will be apparent from the detailed description which follows, taken in conjunction with the accompanying drawings, which together illustrate, by way of example only, features of the present disclosure, and wherein:

FIG. 1 is a schematic diagram showing the use of a circuit measurement circuit according to an example;

FIG. 2 is a schematic diagram showing a first set of sub-components of a circuit measurement circuit according to an example;

FIG. 3 is a schematic diagram showing a second set of sub-components of a circuit measurement circuit according to an example;

FIG. 4 is a circuit diagram showing a circuit measurement circuit according to an example;

FIG. 5 is a flow diagram showing a method of measuring a current according to an example; and

FIG. 6 is a flow diagram showing a method of operating a circuit measurement circuit according to an example.

### DETAILED DESCRIPTION

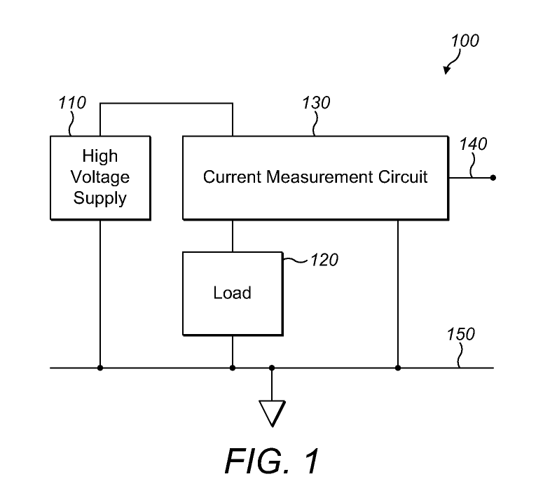

FIG. 1 shows an exemplary arrangement 100 for measuring a current generated when a high-voltage power supply 110 is used to power a load 120. A high-voltage may be considered a voltage in the approximate range of 30 to 100 volts. A very high voltage may be a voltage above this range. The examples described herein may also be applied to supply-voltages outside of these ranges. The load 120 comprises an electrical device. The electrical device may comprise one or more electrical circuits that use a high voltage supplied by the high-voltage power supply 110. The electrical device may comprise any suitable device; some examples are a thermal ink-jet print head or a direct-current (DC) motor.

FIG. 1 shows an exemplary current measurement circuit 130, which is arranged between the high-voltage power supply 110 and the load 120. For example, the current measurement circuit 130 may be arranged on an input power supply line for the electrical device. The current measurement circuit comprises a signal output 140 that outputs a signal representative of the current drawn by the load 120. In certain examples, the signal comprises a voltage signal that is proportional to the input current for the load 120. In the exemplary arrangement of FIG. 1, the high-voltage power supply 110, the load 120 and the current measurement circuit 130 are electrically coupled to a ground connection 150. FIG. 1 shows a ground rail for example only; individual grounded couplings, i.e. individual components individually coupled to ground, or another suitable reference point, may alternatively be used.

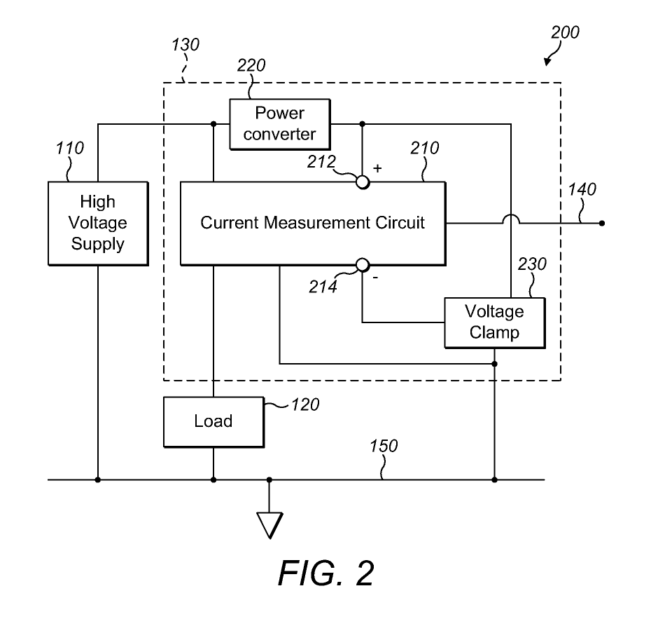

FIG. 2 shows an exemplary arrangement 200 that illustrates a first set of exemplary sub-components of the current measurement circuit 130. In the exemplary arrangement 200, common features from FIG. 1, such as the high-voltage power supply 110, the load 120, signal output 140 and the ground connection 150, are labeled with the reference numerals used in FIG. 1. The first set of sub-components of the current measurement circuit 130 is shown within a dotted line representing said circuit. In the example of FIG. 2, the current measurement circuit comprises a current sensing circuit 210, a power converter 220 and a voltage clamp 230. The current sensing circuit 210 is arranged between the high-voltage power supply 110 and the load 120. As for the example of FIG. 1, the current sensing circuit 210 may be arranged on an input power supply line for the electrical device. The current sensing circuit 210 comprises a positive terminal 212 for the supply of a positive operating voltage and a negative terminal 212 for the supply of a negative operating voltage. The positive terminal 212 is electrically coupled to an output of the power converter 220 to supply a positive operating voltage for the current sensing circuit 210. The negative terminal 214 is electrically coupled to the voltage clamp 230. The voltage clamp 230 is arranged between the positive terminal 212 and the negative terminal 214, i.e. is also electrically coupled to an output of the power converter 220. The current sensing circuit 210 and the voltage clamp 230 are electrically coupled to the ground connection 150. The current sensing circuit 210 outputs a signal on signal line 140 that is representative of the input current drawn by the load 120.

The power converter 220 is arranged to convert a first voltage output by the high-voltage power supply 110 to a second voltage for supply as the positive operating voltage, i.e. for supply to the positive terminal 212. The voltage clamp 230 is arranged to clamp the difference between the positive and negative operating voltages, i.e. to set the voltages seen by the current sensing circuit 210 at the positive terminal 212 and the negative terminal 214. This second arrangement 200 effectively provides a pair of auxiliary power supply rails: a first supply rail at a voltage above the voltage supplied by the high-voltage power supply 110 and a second supply rail acting as a ground rail at a voltage below the first supply voltage, for example in certain cases below a voltage supplied by the high-voltage power supply 110.

The use of the auxiliary power supply rails avoids the need for the input voltage range of the current sensing circuit 210 and/or the output voltage range of the current sensing circuit 210 to accurately extend between the voltage supplied by the high-voltage power supply 110 and the ground connection 150. If the power converter 220 was not supplied then the positive operating voltage seen at the positive terminal 212 would equal the voltage supplied by the high-voltage power supply 110. However, at least the input voltage of the current sensing circuit 210 also operates in a voltage range between the voltage supplied by the high-voltage power supply 110 and the ground connection 150; i.e. at least the input voltage range for the current sensing circuit 210 would match the operating voltage range of the current sensing circuit 210 requiring so-called rail-to-rail operation of the current sensing circuit 210. Typically rail-to-rail operation is difficult to achieve as there will be power dissipation in one or more sub-components of the current sensing circuit 210. Providing rail-to-rail (or near rail-to-rail) operation thus typically requires expensive, and often bespoke, circuits and/or sub-components that have minimal power dissipation. For example, if the power converter was omitted from the examples, a rail-to-rail operational amplifier would be required to operate with input/output voltages equal to a supply the positive terminal 412. This type of operational amplifier is difficult to find, e.g. is less common, and is much more expensive. Using a power converter, the positive terminal 412 voltage is higher than input/output voltages, therefore removing the need for a rail-to-rail operational amplifier; for example, any standard operational amplifier can be used.

The problem described above is compounded by the need for rail-to-rail operation at high voltages, such as the high voltages supplied by the high-voltage power supply 110. In the present example, the use of the voltage clamp 230 enables the difference in the positive and negative operating voltages to be low, e.g. to be in the order of 2 to 4 V rather than 24 V or 32V, the latter being the difference between the voltage supplied by the high-voltage power supply 110 and the ground connection 150. Hence, a need for expensive, difficult to locate and/or complex circuitry is avoided with the exemplary arrangement of FIG. 2. The exemplary arrangement of FIG. 2 enables a simple, small and low-cost solution to be provided that can be easily extended to other high-voltages and even very high voltages.

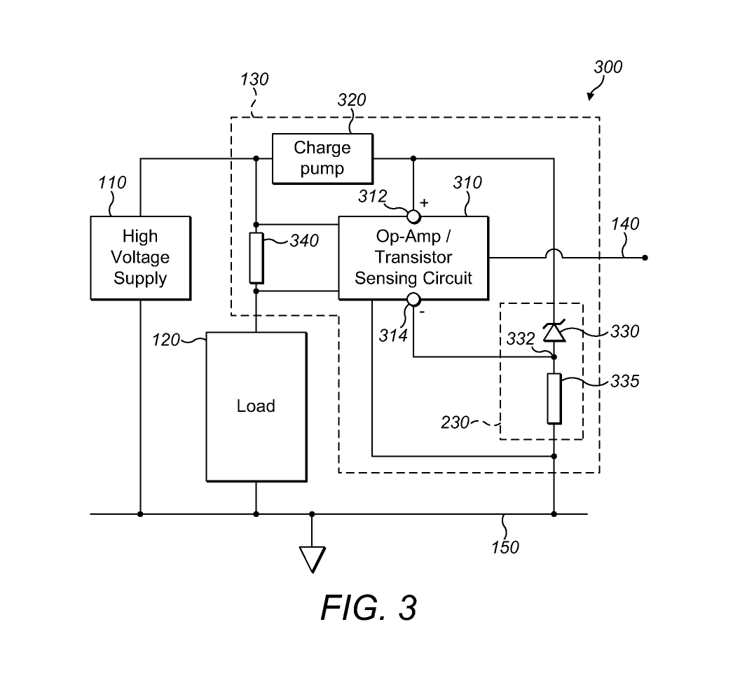

FIG. 3 shows an exemplary arrangement 300 that illustrates a second set of exemplary sub-components of the current measurement circuit 130. For example the second set of exemplary sub-components may represent a particular implementation of the current measurement circuit 130 of FIG. 1 and/or the first set of sub-components of FIG. 2. As in FIG. 2, the second set of sub-components of the current measurement circuit 130 are shown within a dotted line representing said circuit. In the exemplary arrangement 300, common features from FIG. 1, such as the high-voltage power supply 110, the load 120, signal output 140 and the ground connection 150, are labeled with the reference numerals used in FIG. 1. The second set of sub-components comprise an operational amplifier/transistor sensing circuit 310, a charge pump 320, a zener diode 330, a shunt resistive component 335 and a sensing resistive component 340.

The charge pump 320 is electrically coupled to the high-voltage power supply 110, i.e. it has an input voltage equal to the high voltage supplied by the high-voltage power supply 110. The charge pump 320 may be used as the power converter 220 of FIG. 2. A typical charge pump converts one Direct Current (DC) voltage to another DC voltage, in this case a higher DC voltage, using one or more capacitors as energy storage elements; however, any form of charge pump may be used in practice. The charge pump 230 supplies a second voltage that is higher than the voltage supplied by the high-voltage power supply 110 to a positive terminal 312 of the operational amplifier/transistor sensing circuit 310. The positive terminal 312 allows a positive operating voltage equal to the higher second voltage to be supplied to the operational amplifier components of the operational amplifier/transistor sensing circuit 310. This, as described previously, avoids the need for a rail-to-rail operational amplifier. While in this example an operational amplifier/transistor arrangement is used in practice one or more alternate monolithic devices may be used in place of an operational amplifier. In this context, a monolithic device comprises an integrated circuit or chip manufactured by the patterned diffusion of trace elements into the surface of a thin substrate of semiconductor material. An example of a common monolithic device is an operational amplifier.

The zener diode 330 is electrically coupled between an output of the charge pump 320 and a circuit node 332. A cathode of the zener diode 330 is electrically coupled to the output of the charge pump 320 and an anode of the zener diode 330 is electrically coupled to the circuit node 332. The negative terminal 314 allows a negative operating voltage lower than the higher second voltage to be supplied to the operational amplifier component(s) of the operational amplifier/transistor sensing circuit 310. In the present example, the zener diode 330 and the shunt resistive component 335 comprise a shunt regulator that may be used to implement the voltage clamp 230 of FIG. 2. The difference between the positive terminal 312 and the negative terminal 314 is regulated by the zener diode 330, i.e. the difference is equal to the breakdown voltage of the zener diode 330.

The voltage clamp 230 or zener regulator circuit enables a low-voltage, standard operational amplifier to be used in the operational amplifier/transistor sensing circuit 310. In this case, low-voltage means that the operational amplifier is configured to operate with voltages below approximately 30 volts. For example, if the voltage clamp 230 or zener regulator circuit was not in place, an operational amplifier adapted to operate with voltages above 30 volts (i.e. at ‘high’ voltages) would be required. These operational amplifiers are typically expensive and difficult to obtain, as they require suitably adapted high-voltage sub-components and/or materials. In the present example, the resistance of the zener diode 330 decreases in a non-linear manner in response to an applied voltage, such that, for the range of currents that the circuit is designed for, the voltage across the zener diode 330 is approximately constant. This maintains a reasonably stable voltage supply the operational amplifier/transistor sensing circuit 310.

The operational amplifier/transistor sensing circuit 310 is electrically coupled to either side of the sensing resistive component 340. The sensing resistive component 340 is electrically coupled between the high-voltage power supply 110 and the load 120. It enables an input current I_{d} to be sensed by the operational amplifier/transistor sensing circuit 310. The sensing resistive component 340 is typically a high-value (e.g. 1 megaohm) resistor. The operational amplifier/transistor sensing circuit 310 is arranged to convert the sensed current signal to a voltage signal. The voltage signal is then referenced to ground such that it may be easily read by analog and digital systems.

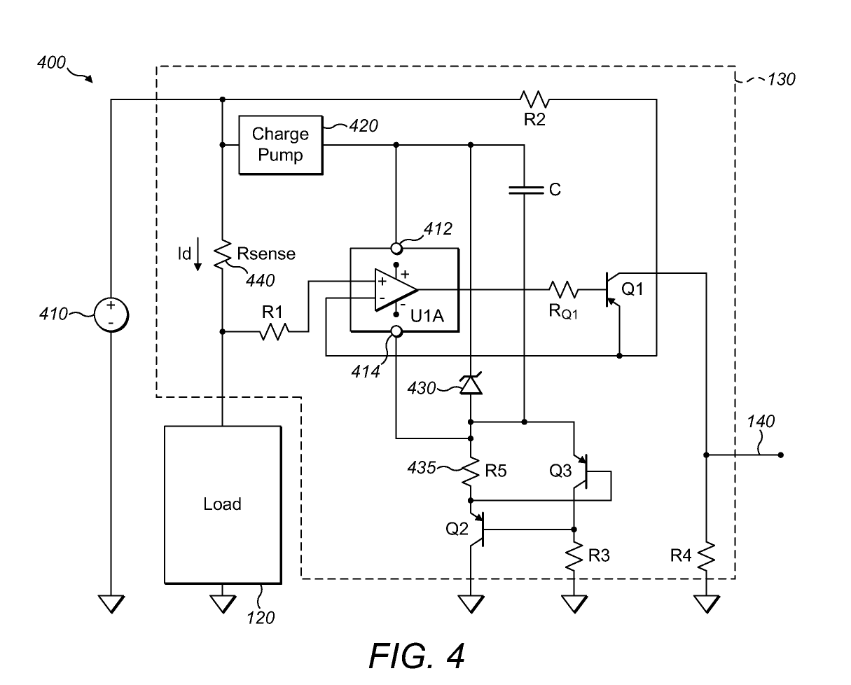

FIG. 4 is a circuit diagram showing a circuit measurement circuit 130 according to an example. FIG. 4 shows a particular exemplary arrangement 400 of electronic components that may be used to implement the circuit measurement circuit 130, as shown in any of FIGS. 1 to 3. The specific component types, values and configurations are representative of an exemplary implementation and may vary for other implementations.

In FIG. 4, the high-voltage power supply 410 comprises a 32V voltage supply. A charge pump 420 is electrically coupled to the high-voltage power supply 410. In the example of FIG. 4, the charge pump 420 is a 5 mA charge pump that may be implemented at a low-cost. The charge pump 420 is arranged to step-up the voltage to 44V, which is supplied to positive terminal 412 of an operational amplifier U1A. The operational amplifier may be, for example, a LM358 supplied by Texas Instruments Inc. of Dallas, Tex. A non-inverting input of the operational amplifier U1A is electrically coupled to one side of a first resistor R1. The other side of the first resistor R1 is electrically coupled to a load-side of a sensing resistor Rₛₑₙₛₑ. The first resistor R1 may comprise, for example, a 332 ohm resistor. The sensing resistor Rₛₑₙₛₑ is electrically coupled between the 32V voltage supply 410 and the load 120. The sensing resistor Rₛₑₙₛₑ may comprise, for example, a 10 megaohm resistor. A power-supply-side of the sensing resistor Rₛₑₙₛₑ is electrically coupled to a second resistor R2. The inverting input of the operational amplifier U1A is electrically coupled to an emitter of a first transistor Q1. The emitter of the first transistor Q1 is also electrically coupled to one side of the second resistor R2, which in this example is equal to R1 in resistive value (i.e. is a 332 ohm resistor). The other side of the second resistor R2 is electrically coupled to the high-voltage power supply 410 and the sensing resistor Rₛₑₙₛₑ. The positive and negative supply rails for the operational amplifier U1A are respectively coupled to the positive terminal 412 and a negative terminal 414. An output of the operational amplifier U1A biases the first transistor Q1 via a first bias resistor R_{Q1}. In this example the first transistor Q1 is a PNP bipolar junction transistor, but other forms of transistor may alternatively be used. The first bias resistor R_{Q1} has a resistance value suitable for biasing the first transistor Q1, in the present example this is 10 kiloohms.

As described above, an emitter of the first transistor Q1 is electrically coupled to the 32V power supply 410 via the second resistor R2. A collector of the first transistor Q1 is electrically coupled to the ground connection 150 via one side of a fourth resistor R4, the other side of which is coupled to ground connection 150. In this example, the fourth resistor has a resistance value of 10 kiloohms. The voltage across the fourth resistor R4 is taken as the signal output 140.

The stepped-up voltage generated by the charge pump 420 is also supplied to the cathode of a zener diode 430. The zener diode 430 may be, for example, a BZX84C-24 supplied by Fairchild Semiconductor International, Inc. of San Jose, Calif. An anode of the zener diode 430 is electrically coupled to a negative terminal 414. The zener diode 430 is also electrically coupled to a fifth resistor R5, which may have a value of 60 ohms. The zener diode 430 is arranged in parallel with capacitor C, which acts as a bypass capacitor. The capacitor C may have a value of 1 microfarad. One side of the fifth resistor R5 is electrically coupled to the anode of the zener diode 430 and another side is electrically coupled to an emitter of a second transistor Q2, which may be a PNP bipolar junction transistor. The collector of the second transistor Q2 is electrically coupled to the ground connection 150. The anode of the zener diode 430, together with one side of the fifth resistor R5 and the capacitor C, is also electrically coupled to an emitter of a third transistor Q3, which may also be a PNP bipolar junction transistor. The base of the third transistor Q3 is electrically coupled to the other side of the fifth resistor R5 and the emitter of the second transistor Q2. A base of the second transistor Q2 and a collector of the third transistor Q3 are coupled to one side of a third resistor R3. Another side of the third resistor R3 is electrically coupled to the ground connection 150. In the present example, the third resistor R5 has a resistance value of 1 kiloohm.

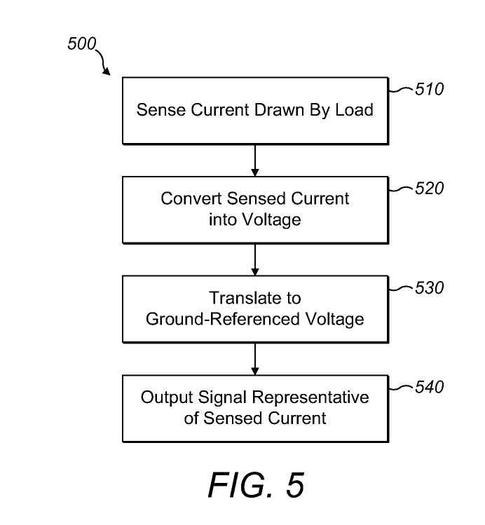

FIG. 5 shows a method 500 of measuring a current according to an example. This method may be applied to at least any of the exemplary arrangements of FIGS. 1 to 4. At step 510, a current drawn by a load is sensed. The load may comprise load 120 and the current may comprise current I_{d} that flows through sensing resistive component 340 or sensing resistor Rₛₑₙₛₑ. In the exemplary arrangement of FIG. 4, the current drawn by the load is sensed via the inputs of the operational amplifier U1A. At step 520, which may occur simultaneously with step 510, a sensed current signal is converted into a voltage signal by a current sensing circuit. The current sensing circuit may comprise current sensing circuit 210 in FIG. 2, the operational amplifier/transistor sensing circuit 310 of FIG. 3 and/or the operational amplifier U1A in FIG. 4. At step 530, which again may occur simultaneously with one or more of the previous steps, the voltage signal from step 520 is translated to a ground-referenced voltage. At step 540, the circuit sensing circuit is used to output a voltage signal representative of the sensed current.

For example, the exemplary arrangement of FIG. 4 utilizes an operational amplifier/transistor pair, U1A-Q1, to generate a current I_{Q1} that is sent to ground via the fourth resistor R4. In FIG. 4, the signal output 140 comprises a voltage signal that is proportional to the input current as per the following formula:

V_{OUTPUT}=K*I_{d}

wherein

K=R4*Rₛₑₙₛₑ/R1

and R4 is the resistance value of the fourth resistor, Rₛₑₙₛₑ is the resistance value of the sensing resistor and R1 is the resistance value of the first resistor, wherein in the example of FIG. 4 the resistance value of the first resistor is assumed to equal the resistance value of the second resistor (i.e. R1=R2).

The method of FIG. 5 may comprise converting a first voltage supplied by a high-voltage power supply to a second voltage, the second voltage being higher than the first voltage. This may be performed by the power convertor 220 of FIG. 2 or the charge pumps 320 and 420 of FIGS. 3 and 4. The second voltage may be supplied to one of the positive terminals 212, 312, and/or 412 shown in FIGS. 2 to 4. In certain cases, a positive operating voltage and/or a negative operating voltage of the circuit sensing circuit are clamped, e.g. such that there is a predefined difference between the two operating voltages. This may be achieved by the voltage clamp 230 of FIG. 2 or at least the zener diodes 330 and 430 of FIGS. 3 to 4. For example, a fixed voltage difference between the positive and negative operating voltages may enable one an operational amplifier as shown in FIG. 4 to operate correctly.

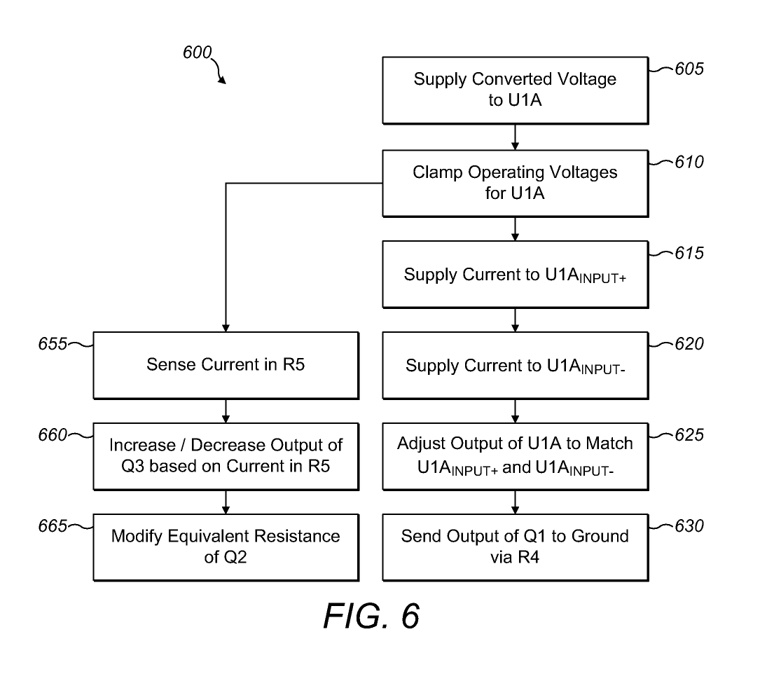

FIG. 6 shows a method 600 of operating the circuit measurement circuit of FIG. 4 according to an example. At step 605, a converted voltage is supplied to the operational amplifier U1A. The converted voltage is a voltage that is higher than a power supply voltage for a load under test; for example, the output of a 5 mA charge pump 420 at 44V. At step 610, the operating voltages for the operational amplifier U1A are clamped, i.e. set in reference to each other; for example, using at least zener diode 430. At step 615, a current signal is supplied to the non-inverting input of the operational amplifier U1A (U1A_{INPUT+}). This is supplied via the first resistor R1. At step 620, a current signal is supplied to the inverting input of the operational amplifier U1A (U1A_{INPUT-}). This is supplied via the second resistor R2 and is modified based on the operation of the first transistor Q1. At step 625, the operational amplifier U1A is arranged to adjust an output voltage such that the voltages at both inputs (i.e. U1A_{INPUT+ and} U1A_{INPUT-}) are the same. In this manner, the operational amplifier U1A and the first transistor Q1 are used to generate a current that flows into the fourth resistor R4, this current being proportional to the sensed current flowing through the sensing resistor Rₛₑₙₛₑ, i.e. current I_{d}. At step 630 this output current is sent to ground via the fourth resistor R4 to enable a voltage referenced to ground to be measured at the signal output 140. The current measurement circuit is configured such that the voltage across the sensing resistor Rₛₑₙₛₑ equals the voltage across the second resistor R2. Hence, the current ratio between these two resistors equals R2/Rₛₑₙₛₑ, i.e. the ratio of the resistance values. As the resistance value of R1 equals the resistance value of R2, this results in the proportionality equation set out above. The voltage that is measured as the signal output 140 is referenced to ground. This enables the signal output 140 to be coupled to an analog-to-digital convertor. An output of such an analog-to-digital convertor may then be read by a microprocessor and/or be used as an input to be read by a computer system.

Method 600 also shows a number of steps that may form part of step 610. In FIG. 4, the third resistor R3, the fifth resistor R5, the second transistor Q2 and the third transistor Q3 form a circuit for stabilizing a current flowing through the zener diode 430. At step 655, the third transistor Q3 is used to sense a current flowing through the fifth resistor R5. The circuit is arranged such that if the sensed current varies from a configured value, for example 10 mA in the implementation of FIG. 4, the third transistor Q3 increases or decreases its output current at step 660. This has the effect of modifying the equivalent resistance of the second transistor Q2 at step 660, in such a way that the configured current value is restored. In this example, the second and third transistors Q2 and Q3 experience high voltages and so need to be configured accordingly. Steps 655 to 665, and the corresponding circuit components in FIG. 4, have the effect of regulating the operating voltages for the operational amplifier U1A. This may be useful in certain, but not necessarily all, cases where a supply voltage and/or a voltage output by the charge pump, varies over a wide range.

The described examples enable currents from high-voltage nodes to be measured. In particular, examples reference an output signal to ground, e.g. to ground connection 150, which results in simpler measurements. The described examples address difficulties experienced when measuring a current into an electrical device, where the device is supplied with a high voltage. By converting a sensed current into a voltage level that is referenced to ground, the voltage level can be easily converted into a digital signal that can be input into a microprocessor. The examples offer a simple, small and cheap solution to measure such a current with a high dynamic range and good output linearity. A further advantage of the described examples is they can be easily extended to very high-voltage supplies, i.e. voltage supplies higher than 32V.

The above arrangements are to be understood as illustrative examples. As used herein “electrically coupled” is to be interpreted as electrically connected either directly or via one or more electronic components. Further arrangements and modifications to those arrangements are envisaged.

It will be understood that the circuitry referred to herein may in practice be provided by a single chip or integrated circuit or plural chips or integrated circuits, optionally provided as a chipset, an application-specific integrated circuit (ASIC), field-programmable gate array (FPGA), digital signal processor (DSP), etc. The chip or chips may comprise circuitry (as well as possibly firmware) for embodying at least one or more of a data processor or processors that are configurable so as to operate in accordance with the described examples. In this regard, the examples may also be implemented at least in part by computer software stored in (non-transitory) memory and executable by the processor, or by hardware, or by a combination of tangibly stored software and hardware (and tangibly stored firmware).

It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the invention, which is defined in the accompanying claims.

1. Apparatus for measuring a current flowing into an electrical device, comprising:
a current sensing circuit comprising at least one monolithic device having a positive operating voltage and a negative operating voltage, wherein said monolithic device is not required to provide rail-to-rail operation, the current sensing circuit being electrically coupled to a power supply for the electrical device, the at least one monolithic device being arranged to enable the apparatus to output a signal representative of the input current from the power supply to the electrical device;
a power converter for converting a first voltage output by the power supply to a second voltage for supply as the positive operating voltage for the at least one monolithic device, the second voltage being higher than the first voltage; and
a voltage clamp arranged to clamp the difference between the positive and negative operating voltages of the at least one monolithic device.

2. Apparatus according to claim 1, wherein the power converter comprises a charge pump.

3. Apparatus according to claim 1, wherein the voltage clamp comprises a zener diode, an output of the power converter being arranged to supply the positive operating voltage based on the second voltage and being electrically coupled to at least a cathode of the zener diode, the negative operating voltage being supplied from a node that is electrically coupled to at least an anode of the zener diode.

4. Apparatus according to claim 1, wherein the at least one monolithic device comprises at least one differential amplifier and the current sensing circuit comprises at least one transistor, the at least one transistor being biased based on the output of the at least one differential amplifier.

5. Apparatus according to claim 4, wherein the current sensing circuit comprises a resistive component electrically coupled between the power supply and the electrical device and at least one input of the differential amplifier is electrically coupled to at least the resistive component.

6. Apparatus according to claim 1, wherein the voltage clamp comprises a voltage regulator arranged to regulate the positive operating voltage and the negative operating voltage in response to changes in one or more of an output of the power supply and an output of the power convertor.

7. Apparatus according to claim 1, wherein the signal representative of the input current from the power supply to the electrical device comprises a voltage signal referenced to ground.

8. Apparatus according to claim 1, wherein the at least one monolithic device is arrange to convert a sensed current signal into a voltage signal.

9. Apparatus according to claim 1, wherein the current sensing circuit is coupled to either side of a sensing resistive component via respective coupling resistive components.

10. Apparatus according to claim 1, wherein the voltage clamp comprises a zener diode in parallel with a bypass capacitor.

11. Apparatus according to claim 1, wherein the electrical device comprises one of an ink-jet print head and a motor.

12. A method of measuring a current flowing into an electrical device, comprising:
sensing a current drawn by the electrical device from a power supply using a current sensing circuit comprising at least one monolithic device having a positive operating voltage and a negative operating voltage, wherein said monolithic device is not required to provide rail-to-rail operation;
converting a first voltage output by the power supply to a second voltage for supply as the positive operating voltage for the at least one monolithic device, the second voltage being higher than the first voltage;
clamping the difference between the positive and negative operating voltages of the at least one monolithic device; and
outputting a signal representative of the input current from the power supply to the electrical device using the at least one monolithic device of the current sensing circuit.

13. A method according to claim 12, wherein converting a first voltage output comprises converting a first voltage using a charge pump.

14. A method according to claim 12, wherein clamping the difference between the positive and negative operating voltages of the at least one monolithic device comprises:
supplying the positive operating voltage using the second voltage; and
clamping the difference between the positive and negative operating voltages using a zener diode.

15. A method according to claim 12, wherein the at least one monolithic device comprises at least one differential amplifier and the current sensing circuit comprises at least one transistor and wherein sensing a current drawn by the electrical device comprises biasing the at least one transistor based on the output of the at least one differential amplifier.

16. A method according to claim 12, wherein sensing a current drawn by the electrical device comprises:
generating a voltage proportional to the input current from the power supply based on the sensed current.

17. A method according to claim 16, wherein the voltage is referenced to ground.

18. A method according to claim 12, wherein damping the difference between the positive and negative operating voltages comprises regulating the positive and negative operating voltages in response to changes in one or more of the first and second voltages.

19. A method according to claim 12, wherein sensing a current drawn by the electrical device comprises sensing a current flowing through a sensing resistive component coupled to the current sensing circuit via respective coupling resistive components.

20. A method for measuring a current flowing into an ink jet print head, comprising:
sensing a current drawn by the ink jet print head from a power supply using a current sensing circuit comprising at least one monolithic device having a positive operating voltage and a negative operating voltage, wherein said monolithic device is not required to provide rail-to-rail operation;
converting a first voltage output by the power supply to a second voltage for supply as the positive operating voltage for the at least one monolithic device, the second voltage being higher than the first voltage;
clamping the difference between the positive and negative operating voltages of the at least one monolithic device; and
outputting a signal representative of the input current from the power supply to the ink jet print head using the at least one monolithic device of the current sensing circuit.
